(19) United States
(12) Patent Application Publication
(10) Pub. No.: US 2016/0211042 A1
(43) Pub. Date: Jul. 21, 2016

(54) DEVICES AND METHODS FOR CONVERTING ENERGY FROM RADIATION INTO ELECTRICAL POWER

(71) Applicant: Idaho State University, Pocatello, ID (US)

(72) Inventor: Eric A. Burgett, Pocatello, ID (US)

(21) Appl. No.: 14/997,210

(22) Filed: Jan. 15, 2016

Related U.S. Application Data
(60) Provisional application No. 62/104,412, filed on Jan. 16, 2015.

(51) Int. Cl. G21H 1/06; H01L 31/115

(52) U.S. Cl. CPC G21H 1/06; H01L 31/115

(57) ABSTRACT

Devices and methods are presented for converting energy from radiation into electrical power. In one illustrative embodiment, a device for converting energy from radiation into electrical power includes a diode formed of a semiconductor material capable of mitigating radiation damage by operating at temperatures greater than 300° C. The device also includes a radiation source comprising an isotope emitting alpha particles. In another illustrative embodiment, a device for converting energy from radiation into electrical power includes a diode formed of a semiconductor material comprising uranium oxide, UO_{2±x}, where 0≦x≦0.5. The device also includes a radiation source comprising an isotope emitting alpha particles. The semiconductor material may include a single-crystal of uranium oxide. Other devices and methods are presented.

### CROSS-REFERENCE TO RELATED APPLICATIONS

This application claims the benefit of U.S. Provisional Application No. 62/104,412, filed Jan. 16, 2015.

### FIELD

This disclosure relates generally, to devices and methods for converting energy from radiation into electrical power.

### BACKGROUND

Nuclear isotopes offer energy densities virtually unmatched by chemical compounds and their related reaction processes. However, utilization of nuclear isotopes to generate electrical power involves managing radiation damage in materials containing (and proximate to) such isotopes. Conventional approaches to using nuclear isotopes have revolved around indirect conversion processes where energy from radiation is first converted to an intermediate energy form before subsequent conversion into electrical power. The intermediate energy form is most commonly thermal (e.g. heat), which is generated and stored within a material tolerant to radiation damage.

Indirect conversion processes, however, require additional equipment that can increase maintenance costs, decrease reliability, and introduce inefficiencies into an energy conversion process. Direct conversion processes are therefore highly sought after by the nuclear industry due to their simpler implementation and improved efficiencies. Devices for direct conversion processes typically incorporate semiconductor materials to absorb radiation and produce electrical power. Unfortunately, existing semiconductors offer poor tolerance to radiation damage at fluence rates needed for high power output, and in such environments, degrade quickly under exposure to radiation. Semiconductor materials having improved radiation hardness and longer operational lifetimes are desired.

### SUMMARY

The embodiments described herein relate to devices and methods for converting energy from radiation into electrical power. In one illustrative embodiment, a device for converting energy from radiation into electrical power includes a diode formed of a semiconductor material capable of mitigating radiation damage by operating at temperatures greater than 300° C. The device also includes a radiation source comprising an isotope emitting alpha particles. In some instances, the diode is a plurality of diodes electrically-coupled in series, in parallel, or any combination thereof.

In another illustrative embodiment, a device having uranium oxide for converting energy from radiation into electrical power includes a diode formed of a semiconductor material comprising uranium oxide, UO_{2±x}, where 0≦x≦0.5. The device also includes a radiation source comprising an isotope emitting alpha particles. In various instances, the semiconductor material includes a single-crystal of uranium oxide. A p-type diode portion of the diode may include over-stoichiometric uranium oxide, UO₂₊ₓ. An n-type diode portion of the diode comprises under-stoichiometric uranium oxide, UO₂₋ₓ.

In an additional illustrative embodiment, a method for converting energy from radiation into electrical power includes the step of absorbing radiation within a diode, the radiation comprising alpha particles emitted from an isotope. The diode is formed of a semiconductor material capable of mitigating radiation damage by operating at temperatures greater than 300° C. The method also includes the step of generating electrical power from the diode in response to the absorbed radiation. In certain instances, the method further includes the step of altering an operating temperature of the diode to an annealing temperature. Other devices and methods are presented.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A is a perspective view of a portion of a device for converting energy from radiation into electrical power, according to an illustrative embodiment;

FIG. 1B is a perspective view of a portion of a device for converting energy from radiation into electrical power and having a plurality of trenches for defining a trench pattern, according to an illustrative embodiment; and

FIG. 2 is a plot of data representing an annealing of radiation damage in a semiconductor material formed of uranium oxide.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The embodiments include diodes formed of semiconductor materials that can be annealed to mitigate radiation damage. Such annealing can be accomplished during operation of the diode, and hence, while the diode is converting energy from radiation into electrical power. The semiconductor materials are also able to preserve a structure of the diodes at high temperature, which in some embodiments, may include operating temperatures in excess of 2000° C. The diodes formed of these semiconductor materials can be incorporated into devices having sources of radiation, such as sources of alpha particles. When incorporated into these devices, the diodes function analogously to a battery (e.g., an alpha-voltaic nuclear battery).

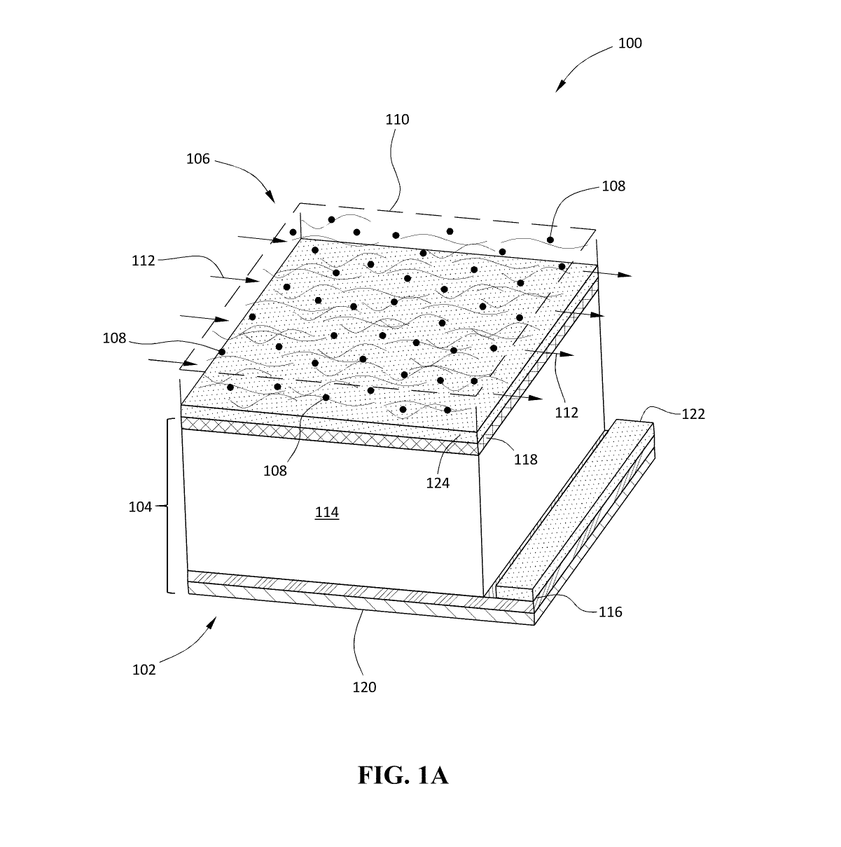

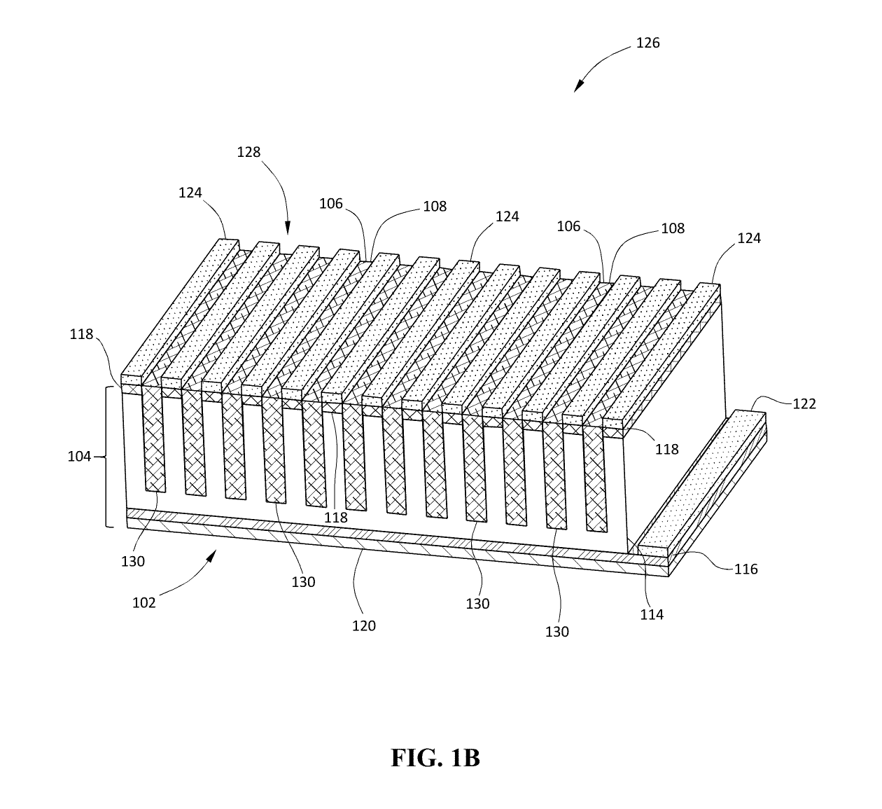

Referring now to FIG. 1A, a perspective view is presented of a portion of a device 100 for converting energy from radiation into electrical power, according to an illustrative embodiment. Non-limiting examples of radiation that can be converted by the device 100 include alpha particles, neutron particles, beta particles, gamma rays, and combinations thereof. Such radiation may have energies greater than 10 eV for the charged particles (i.e., alpha particles, beta particles, etc.) or 0.1 meV for neutrons.

The device 100 includes a diode 102 formed of a semiconductor material 104 capable of mitigating radiation damage by operating at temperatures greater than 300° C. The semiconductor material 104 may be an amorphous semiconductor material, a polycrystalline semiconductor material, or a single-crystal semiconductor material. The semiconductor material 104 can be annealed at a temperature greater than 300° C. to regenerate a state substantially undamaged by radiation. The state substantially undamaged by radiation may correspond to a loss in conversion efficiency of the diode 102 no greater than 15% relative to a semiconductor material unexposed to radiation.

In other embodiments, the semiconductor material can be annealed at a temperature greater than 500° C., while in still other embodiments the semiconductor material cam annealed at a temperature greater than a 1000° C. In yet other embodiments, the semiconductor can be annealed at a temperature ranging from 300° C. to 2000° C. Such annealing, in some embodiments, may occur continuously or intermittently during operation of the diode 102 (i.e., when the device 100 is converting energy from radiation into electrical power). In other embodiments, such annealing may also occur during an offline time period when the diode 102 is not operating. Annealing prevents the diode 102 from degrading below a performance threshold as radiation is progressively absorbed within the semiconductor material 104.

In some embodiments, the semiconductor material 104 is capable of mitigating radiation damage by operating at temperatures greater than 500° C. In further embodiments, the semiconductor material 104 is capable of mitigating radiation damage by operating at temperatures greater than 1000° C. In other embodiments, the semiconductor material 104 is capable of mitigating radiation damage by operating at temperatures between 300° C. and 2000° C.

In some embodiments, the semiconductor material 104 includes an oxide semiconductor having a majority component that includes an actinide element. In these embodiments, the majority component is greater, by mole fraction, than a total amount of other elements, excluding oxygen. In further embodiments, the semiconductor material 104 includes uranium oxide, UO_{2±x}, where 0≦x≦0.5.

The device 100 also includes a radiation source 106 comprising an isotope 108 emitting alpha particles. In some embodiments, the radiation source 106 further comprises an isotope emitting beta particles. In FIG. 1A, the isotope 108 is depicted as being dispersed within a volume 110. However, this depiction is for purposes of clarity only. For example, and without limitation, the radiation source 106 may be formed entirely of the isotope (e.g., a molten fluid of 210-Po, a solid body of 241-Am, etc.). In general, the radiation source 106 may contain any concentration of isotopes therein. In some embodiments, the concentration of isotopes corresponds to a specific activity a specific activity less than 200 GBq/g. In other embodiments, the concentration of isotope corresponds to a specific activity greater than 500 Gbq/g.

In some embodiments, the radiation source 106 may be external to the semiconductor material 104, such as shown in FIG. 1A. In other embodiments, the radiation source 106 may also reside, in whole or in part, within the semiconductor material 104. For example, and without limitation, the radiation source 106 may include embedded isotopes within the semiconductor material 104. Such embedded isotopes may involve a substitution of unstable isotopes for stable isotopes within the semiconductor material 104. Embedded isotopes may also involve an implantation of unstable isotopes in the semiconductor material 104. Other types of embedded isotopes are possible.

When external to the semiconductor material 104, the radiation source 106 may be a solid phase, a liquid phase, a gas phase, or any combination thereof. The radiation source 106 may be directly in contact with the diode 102 or proximate the diode 102 with a gap there between. The radiation source 106 may also be any combination of solid, liquid, and gas phases that allows flow, i.e., a fluid. In FIG. 1A, the radiation source 106 is depicted as a fluid flowing through the volume 110. A motion of flow is indicated by arrows 112. The fluid is in contact with the diode 102. However, this depiction is for purposes of illustration only. Other configurations are possible for the radiation source 106. In some embodiments, the radiation source 106 includes a solid in contact with the diode 102. In some embodiments, the radiation source 106 includes a fluid in contact with the diode 102.

The device 100 may be designed for “low” power or “high” power applications. In general, a power density of the device 100 is inversely proportional to a half life of isotopes included in the radiation source 106, i.e., isotopes with shorter half-lives produce more power per unit mass than isotopes with longer half-lives. Isotopes with shorter half-lives are associated with higher specific activities than isotopes with longer half-lives.

In some embodiments, the radiation source 106 has a specific activity less than 200 GBq/g. In these embodiments, the radiation source 106 may include 232-Th, 238-U, 241-Am or any combination thereof. The radiation source 106 may allow the device 100 to generate electric power less than 0.1 kW per gram of radiation source (i.e., “low” power). Such “low” power may enable the device 100 to have an operational lifetime that exceeds 10 years. In certain instances, the operational life time may exceed 20 years.

In other embodiments, the radiation source 106 can have a specific activity greater than 500 Gbq/g. In such embodiments, the radiation source 106 may include 238-Pu, 277-Ac, 244-Cm, 210-Po, or any combination thereof. The radiation source 106 may allow the device 100 to generate electric power greater than 0.1 kW per gram of radiation source (i.e., “high” power). When configured for “high power”, the operational lifetime of the device 100 may be up to 5 years. In various instances, the operational lifetime of the device 100 may be up to 10 years.

It will be appreciated that the radiation source 106 can produce other forms of radiation in addition to alpha-particle radiation. These other forms of radiation can include beta particles, gamma rays, X-rays, neutrons, nuclear fragments from spontaneous fission, etc. For example, and without limitation, the radiation source 106 may comprise isotopes that emit beta particles. Such isotopes may be in addition to the isotope 108 (e.g., the one or more isotopes emitting beta radiation). Such isotopes may also be unstable daughter isotopes that result from a decay of the isotope 108. In another non-limiting example, beta particles absorbed within radiation source 106 or the semiconductor material 104 may produce X-ray radiation upon being decelerated (i.e., a bremsstrahlung secondary radiation).

In some embodiments, the isotope 108 can decay directly into a stable isotope. In other embodiments, the isotope 108 can decay through a series of unstable daughter isotopes until a final stable isotope is reached. In still other embodiments, the isotope 108 includes a first portion of isotopes that can decay directly into the stable isotope and a second portion of isotopes that can decay through the series of unstable daughter isotopes until the final stable isotope is reached.

Within the diode 102, the semiconductor material 104 exhibits doped regions that correspond to diode portions having a majority of charge carriers that are positively-charged (i.e., holes) or negatively-charged (i.e., electrons). The latter represent p-type diode portions and the former represent n-type diode portions. The semiconductor material 104 may also exhibit undoped regions that correspond to diode portions having charge carriers in equal proportions (i.e., substantially equal proportions of holes and electrons). Such undoped regions are often referred to by those skilled in the art as “intrinsic” and represent i-type diode portions.

Doped regions within the semiconductor material 104—whether corresponding to p-type diode portions or n-type diode portions—may be formed using any type of dopant and corresponding dopant distribution. Non-limiting examples of dopant distributions include uniform distributions and gradient distributions. Doped regions may be formed by substituting one element for another in the semiconductor material 104 or by altering its compositional stoichiometry. In some embodiments, p-type diode portions or n-type diode portions in the semiconductor material 104 are formed by varying oxygen stoichiometry, by substituting elements, or both. For example, and without limitation, the semiconductor material 104 may include uranium oxide, UO₂. A p-type region may be formed by substituting Y or La for U in predetermined amounts. Alternatively, an n-type region may be formed by lowering an oxygen stoichiometry to a predetermined under-stoichiometry, i.e., UO₂₋ₓ, where x represents the predetermined under-stoichiometry. It will be understood that dopants vary depending on a composition of the semiconductor material 104. As such, the example presented herein is not intended to limit the composition of semiconductor material 104 or its possible dopants.

The semiconductor material 104 may have any number and combination of junctions between p-type diode portions, n-type diode portions, and i-type diode portions in order to define a structure of the diode 102. For example, and without limitation, the diode 102 may exhibit a p-n structure, a p-i-n structure, an n-p-n structure, or a p-n-p structure. Other structures are possible. FIG. 1A depicts the diode 102 as having an i-type diode portion 114 sandwiched between a p-type diode portion 116 and an n-type diode portion 118 (i.e., the p-i-n structure). However, this depiction is for purposes of illustration only. In some embodiments, the diode 102 includes a p-n structure or a p-i-n structure.

It will be appreciated that the semiconductor material 104 exhibits a thermochemistry such that, when exposed to elevated temperatures (e.g., greater than 300° C.), the structure of the diode 102 is preserved. This aspect of the semiconductor material 104 allows the diode 102 to provide diode functionality at temperatures that simultaneously anneal the semiconductor material 104. Those skilled in the art can therefore select an operating temperature for the at least on diode 102 that allows a conversion of radiation energy into electrical power, but at an output substantially unaffected by a cumulative exposure to radiation. The output may vary by no more than 15% when compared to an initial output produced by the diode before exposure to radiation.

A band-gap of the semiconductor material 104 may be selected by those skilled in the art to match the operating temperature of the diode 102, to establish a desired output voltage from the diode 102, or both. Such selection may include considerations of an annealing temperature for the semiconductor material 104. In some embodiments, the semiconductor material has a band gap ranging from 0.5 to 3.0 eV. In other embodiments, the semiconductor material 104 has a band gap ranging from 3.0 to 6.0 eV. In still other embodiments, the semiconductor material 104 has a band gap ranging from 6.0 to 12.0 eV. Values for the aforementioned band gaps are referenced to room temperature (i.e., 300 K) and may be direct band gaps or indirect band gaps.

The band gap of the semiconductor material 104 can be “tuned” (i.e., selected) by alloying of a base material in the semiconductor material 104 with another material. For example, and without limitation, the semiconductor material 104 may include uranium oxide as a base material. In certain instances, the base material of uranium oxide can be alloyed with a yttrium oxide material, a bismuth oxide material, a copper oxide material, a strontium oxide material, a calcium oxide material, or any combination thereof, to decrease the band gap. In other instances, the base material of uranium oxide can be alloyed with a silicon oxide material, an aluminum oxide material, a beryllium oxide material, or any combination thereof, to increase the band gap. In still other instances, the base material of uranium oxide can be doped with a thorium oxide material, a lanthanum oxide material, a lutetium oxide material, or any combinations thereof, to increase the band gap.

The semiconductor material 104 may also have a thermal conductivity greater than 1 W/(m·K), as measured at 20° C. This range of thermal conductivity may improve a temperature uniformity of the diode 102 during operation, thereby inhibiting a formation of “hot spots” or “cold spots”. “Hot spots” may induce premature failure of the diode 102, while “cold spots” may induce undesired solidification of the radiation source 106 if including the liquid phase. Improved annealing of the semiconductor material 104 may also result within this range of thermal conductivity. In some embodiments, the semiconductor material has a thermal conductivity between 1-100 W/(m·K), as measured at 20° C.

In some embodiments, the diode 102 includes a substrate 120. In these embodiments, the substrate 120 serves as a support, which may include support during fabrication of the diode 102. The substrate 120 may allow a growth of p-type diode portions, n-type diode portions, and i-type diode portions thereon, including a cumulative growth of such portions (e.g., to form stacks of diode portions). Growth of diode portions may involve deposition processes such as chemical vapor deposition (CVD), plasma-enhanced chemical vapor deposition (PECVD), metal organic chemical vapor deposition (MOCVD), molecular beam epitaxy (MBE), physical vapor deposition (PVD), pulsed laser deposition (PLD), evaporative deposition, and sputtering. Other deposition processes are possible.

In further embodiments, the substrate 120 is formed of the semiconductor material 104. In such embodiments, the substrate 120 may be amorphous, polycrystalline, or single crystal. The substrate 120 may have any type of electronic conductivity, including p-type electronic conductivity, n-type electronic conductivity, and i-type electronic conductivity. In FIG. 1A, the substrate 120 is depicted in contact with the p-type diode portion 116, and in this instance, exhibits p-type electronic conductivity. However, this depiction is not intended as limiting. Other configurations are possible for the substrate 120. In some instances, the substrate 120 may serve as the i-type diode portion 114, the p-type diode portion 116, or the n-type diode portion 118.

In some embodiments, the device 100 includes a connector 122, 124 coupled to the diode 102 and formed of an electrically-conductive material stable to at least 300° C. Such stability includes chemical stability to the semiconductor material 104. The connector 122, 124, may be coupled to the p-type diode portion 116 or the n-type diode portion 118. In FIG. 1A, the device 100 is depicted as having two contacts, i.e., a first contact 122 coupled to the p-type diode portion 116 and a second contact 124 coupled to the n-type diode portion 118. However, this depiction is not intended as limiting. Other contact configurations and geometries are possible.

Non-limiting examples of the electrically-conductive material include metals comprising Al, Ti, Au, Mo, Ta, W, Re, Os, Ir, and Pt. The electrically-conductive material may also be an electrically-conductive ceramic such as ZnO:Ga, Ga₂O₃:Zn, In₂O₃:Sn, and GaN. In some embodiments, the electrically-conductive material is stable to at least 1200° C. In other embodiments, the electrically-conductive material is stable up to 2000° C. The connector 122, 124 may vary in composition depending upon whether its coupling is to the p-type diode portion 116 or to the n-type diode portion 118. This variation may improve chemical stability, carrier collection efficiency, or both.

In some embodiments, the radiation source 106 may contact the diode 102 at a surface of the connector 122, 124, as shown in FIG. 1A for the second connector 124. In these embodiments, the radiation source 106 may be electrically conductive. Such electrical conductivity may be greater than 1.0×10⁵ S/m at 20° C. For example, and without limitation, the radiation source 106 may be an electrically-conductive fluid, such as a molten body of 210-Po. In another non-limiting example, the radiation source 106 may be an electrically-conductive solid, such as a solid layer of 241-Am. When electrically-conductive and in contact with the connector 122, 124, the radiation source 106 may function as part of the connector 122, 124. However, in certain instances, the radiation source 106 may replace the connector 122, 124 entirely (i.e., the radiation source 106 may contact the p-type diode portion 116 or the n-type diode portion 118 directly).

In operation, the device 100 converts energy from radiation into electrical power. The radiation source 106 supplies radiation that is received by the diode 102. In embodiments having embedded isotopes, some or all of this radiation may originate within the semiconductor material 104. Radiation is produced by a decay of isotopes associated with the radiation source 106, which includes the isotope 108. During decay, the isotope 108 emits an alpha-particle. Depending on a mass number, the isotope 108 may decay directly into a stable isotope, decay through the series of unstable daughter isotopes until a final stable isotope is reached, or both. In general, radiation from the radiation source 106 may include alpha-particles, beta particles, gamma rays, and combinations thereof. Other types of radiation may be possible. Beta particles, if emitted, may decay under deceleration to further produce X-rays (i.e., bremsstrahlung secondary radiation).

Radiation from the radiation source 106 is absorbed within the diode 102, which may involve any diode portion therein. An availability of diode portions depends on the structure of the diode 102. Those skilled in the art may apportion a diode volume among available diode portions to bias radiation absorption within one or more particular portions. In FIG. 1A, the i-type diode portion 114 occupies a greater volume than the p-type diode portion 116 or the n-type diode portion 118. This apportionment biases radiation absorption to the i-type diode portion 114. However, it will be understood that other structures and apportionments are possible.

Absorption of radiation within the diode 102 ionizes the semiconductor material promoting electrons to excited states within diode portions formed of the semiconductor material 104. Such ionization leaves empty states in an electronic band structure of the semiconductor material 104 that correspond to holes. Electrons and holes are produced in pairs, with the former serving as negative charge carriers and the latter serving as positive charge carriers. Due to the structure of the diode 102, electrons and holes separate and accumulate on opposite sides of the diode 102. In the diode 102 of FIG. 1A, such separation involves charge carrier motion from the i-type diode portion 114 to the p-type diode portion 116, where electrons accumulate, and to the n-type diode portion 118, where holes accumulate. Accumulation of electrons and holes on opposite sides of the diode 102 creates an electric field therein.

The electrical field induces a voltage potential between the first connector 122 and the second connector 124. In embodiments where the radiation source 106 is electrically-conductive, the radiation source 106 may serve part of or replace the connector 122, 124. The first connector 122 and the second connector 124 may be coupled to an electrical circuit to allow the voltage potential to drive an electric current.

The electric current represents a flow of electrons from the p-type diode portion 116, through the electrical circuit, and to the n-type diode portion 118. The first connector 122 collects electrons accumulated in the p-type diode portion and transfers the collected electrons to the electrical circuit. The second connector 124 receives electrons from the electrical circuit and delivers the received electrons into the n-type diode portion 118, where the delivered electrons neutralize holes accumulated therein. Thus, the device 100 can function analogously to a battery and supply electrical power to the electrical circuit. The electrical circuit may have any type, number, and combination of electrical-power consuming devices. The electrical power circuit may also include power inverters to convert DC electrical power from the device 100 to AC electrical power. Other devices are possible in the electric circuit.

It will be appreciated that the electrical power supplied by the device 100 may scale with the specific activity of the radiation source 106. A “low” electrical power of less than 0.1 kW per gram of radiation source may be supplied when the specific activity is less than 200 GBq/g. A “high” electrical power of greater than 0.1 kW per gram of radiation source may be supplied when the specific activity is greater than 500 GBq/g. In general, those skilled in the art can select a power output of the device 100 by controlling which isotopes are utilized by the radiation source 106, including selection of a concentration of such isotopes. In embodiments having embedded isotopes within the semiconductor material 104, the device 100 may utilize embedded isotopes having a half-life greater than 200 years (e.g., 234-U, 235-U, etc.) to supply a persistent “baseline” electrical power.

In some embodiments, the diode 102 is a plurality of diodes electrically-coupled in series, in parallel, or any combination thereof. In these embodiments, the radiation source 106 is shared in common among the plurality of diodes. The plurality of diodes may enable those skilled in the art to engineer the device 100 to supply predetermined magnitudes of voltage, electrical current, or both. Moreover, the plurality of diodes may be electrically-coupled to one or more power inverters so that the device 100 supplies AC electrical power. For example, and without limitation, the plurality of diodes can be electrically-coupled to one or more power inverters to supply 480 kVA.

Radiation absorption within the diode 102 involves a penetration of radiation into the semiconductor material 104, which includes alpha particles. Such penetration may displace atoms within the semiconductor material 104, generating defects that correspond to radiation damage. Non-limiting examples of defects include vacancy defects, interstitial defects, cluster defects, ionization-track defects, and threading defects. Other defects are possible. Penetration of alpha particles, in particular, may damage the semiconductor material 104 by depositing helium nuclei therein, which become entrapped. (Alpha particles correspond to helium nuclei.) Entrapped helium nuclei can passivate the semiconductor material 104, especially at junctions between diode portions. Such passivation stems from cluster defects created by the entrapped helium nuclei, which may also involve displaced dopants. In general, defects from radiation damage can cause a premature recombination of electron-hole pairs, degrading a performance of the diode 102.

To mitigate radiation damage, the operating temperature of the diode 102 may be altered to anneal the semiconductor material 104. Such annealing generates thermal energy sufficient to “heal” the semiconductor material 104. At the annealing temperature, a free energy of the semiconductor material 104 is such that a presence of defects is energetically unfavorable. Annealing also establishes thermal energies sufficient to diffuse entrapped helium nuclei out of the semiconductor material 104. Thus, by operating the diode 102 at an annealing temperature above 300° C., the semiconductor material 104 can regenerate a state substantially undamaged by radiation. The state substantially undamaged by radiation may correspond to a loss in conversion efficiency of the diode 102 no greater than 15% relative to a semiconductor material unexposed to radiation. Such operation may be continuous during electrical power generation, intermittent during electrical power generation, or during periods when the device 100 is offline. This operational advantage is not found in conventional alpha-voltaic and beta-voltaic nuclear batteries, which are not designed to tolerate temperatures higher than 300° C.

The operating temperature of the diode 102 may be altered by controlling heat flow into the diode 102. Heat flow into the diode 102 may involve heat generated by absorbing radiation within the semiconductor material 104. Heat flow into the diode 102 may also involve conductive, convective, or radiative heat supplied by the radiation source 106 (i.e., when external to the diode 102). In embodiments having embedded isotopes, heat may be generated within the semiconductor material 104 by internal irradiation.

The operating temperature of the diode 102 may also be altered by controlling heat flow out of the diode 102. Heat flow out of the diode 102 may involve a heat sink thermally-coupled to the diode 102. A radiation shield may be thermally-coupled to the heat sink to provide additional surface area for heat transfer to an ambient environment. In some embodiments, the radiation shield is formed of a metal having a melting temperature below 500° C., such as lead, sodium, or bismuth. In such embodiments, the metal provides a heat of fusion that, during melting, absorbs additional heat. This absorption of additional heat may be beneficial if a cooling system of the device 100 fails. Heat flow out of the diode 102 may also involve a heat exchanger thermally-coupled to the diode 102. In some embodiments, heat flow out of the diode 102 may involve conductive, convective, or radiative heat delivered to the radiation source 106 (i.e., external to the diode 102).

By manipulating heat flows into and out of the diode 102—including heat generated within the diode 102—the operating temperature can be increased, decreased, or held stable. It will be appreciated that the radiation source 106 may be selected to produce a fluence rate of radiation sufficient to anneal the semiconductor material 104 while enabling high outputs of electrical power (i.e., greater than 0.1 kW per gram of radiation source). This advantage stems from a tolerance of the semiconductor material to temperatures greater than 300° C. In addition to “healing” radiation damage, at annealing temperatures the semiconductor material retains the p-type diode portions, n-type diode portions, i-type diode portions (if present) necessary for operation of the diode 102.

It will be appreciated that, during decay, an isotope may emit radiation in any direction. If a pathway of the emitted radiation fails to intersect the diode 102, energy associated with this decay event is lost, reducing a conversion efficiency of the device 100. In some embodiments, the diode 102 includes a trench pattern disposed along a surface thereof. In these embodiments, the trench pattern allows the diode 100 to present a greater solid angle of capture to the radiation source 106. The greater solid angle of capture increases a probability of absorbing radiation within the semiconductor material 104.

FIG. 1B presents a perspective view of a portion of a device 126 for converting energy from radiation into electrical power and having a plurality of trenches 128 for defining a trench pattern, according to an illustrative embodiment. The plurality of trenches 128 enhances the capture of radiation within the diode 102. Such enhancement results from increasing a solid angle of capture presented to the radiation source 106. Features shared in common between FIGS. 1A & 1B are indicated with similar reference numerals.

The radiation source 106 is partitioned between individual trenches 130 in the plurality of trenches 128, which may involve conformal contact. In FIG. 1B, the radiation source 106 is depicted as a plurality of solid bodies disposed with the trench pattern. The radiation source 106 contacts the i-type diode portion 114 and the n-type diode portion 118. However, this depiction is not intended as limiting. The radiation source may occupy any volume of the plurality of trenches 128 and may contact any diode portion of the diode 102. Such contact may include the connector (e.g., the second connector 124). Moreover, the radiation source 106 need not be restricted to the solid phase. In some embodiments, the radiation source 106 includes a solid in conformal contact with the trench pattern. In other embodiments, the radiation source includes a fluid in conformal contact with the trench pattern.

In FIG. 1B, the trench pattern is illustrated as a parallel array of linear trenches. However, the trench pattern may have any type of pattern capable of forming channels within the diode 102. Non-limiting examples of trench patterns include sinusoidal patterns, triangular-wave patterns, and square-wave patterns. Entry ports into the trench pattern may be enlarged by etching the semiconductor material along a corresponding side. In embodiments where the radiation source 105 is a fluid, such enlarged entry ports may increase wicking of the radiation source 106 into the plurality of trenches 128. Dimensions of the trench pattern may be engineered to improve wicking or flow of the fluid through the plurality of trenches 128. The engineered dimensions may reduce a fluid pressure needed to transport the fluid through the diode 102.

Dimensions of the trench pattern may also be selected by those skilled in the art to maximize collection of radiation within the diode 102. Non-limiting examples of such dimensions include a trench width, a trench depth, a trench spacing, and an aspect ratio (i.e., a ratio of trench depth to trench width). For example, and without limitation, dimensions of the trench pattern may be selected to match a stopping distance of alpha particles. In some embodiments, the trench pattern has an aspect ratio of up to 100:1, a width ranging from 10 nm to 20 μm, and a depth ranging from 12 μm to 1 mm. In these embodiments, the trench pattern may increase the collection efficiency of alpha particles from the radiation source 106. However, improvements in collecting other forms of radiation (e.g., beta particles) are possible.

According to an illustrative embodiment, a device includes uranium oxide for converting energy from radiation into electrical power. The device is analogous to the device 100 described in relation to FIGS. 1A & 1B. The device includes a diode formed of a semiconductor material comprising uranium oxide, UO_{2±x}, where 0≦x≦0.5. The device also includes a radiation source having an isotope emitting alpha particles. In some embodiments, the semiconductor material includes a single-crystal of uranium oxide. The single crystal of uranium oxide may have an as-grown defect density of less than 10⁴ defects/cm⁻³ and an as-grown impurity concentration of less than 10¹² impurities/cm⁻³. In further embodiments, the as-grown impurity concentration is less than 10¹⁰ impurities/cm⁻³.

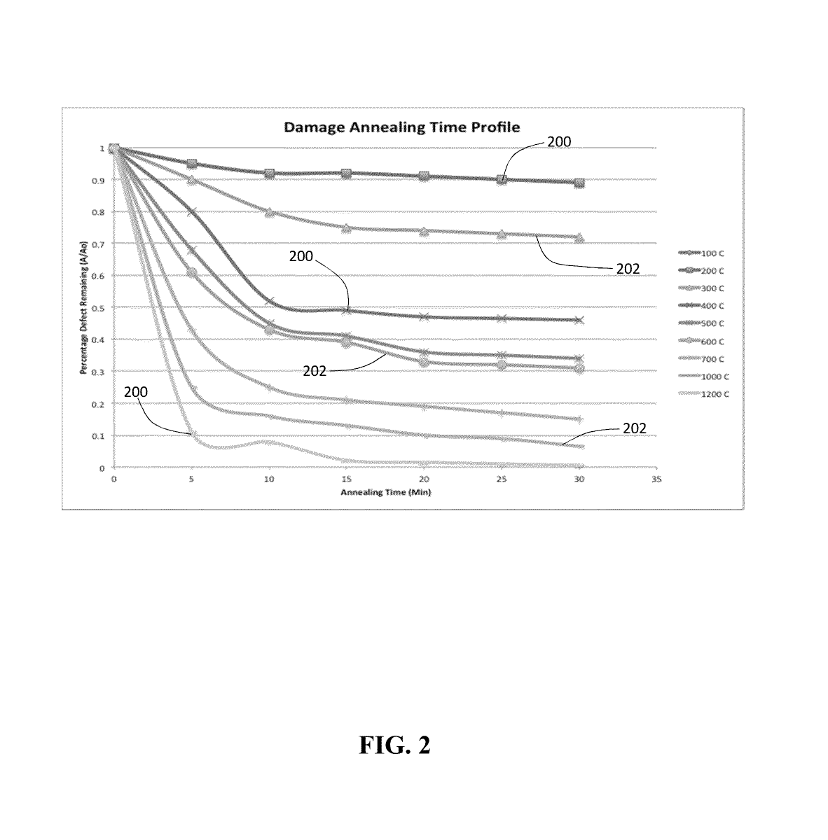

FIG. 2 presents a plot of data representing an annealing of radiation damage in a semiconductor material formed of uranium oxide. A percentage of defects remaining, normalized to unity, is indicated by the ordinate. An annealing time is given by the abscissa. Individual data points 200 indicate the percentage of defects remaining after a given duration of annealing time. Data points 200 grouped by isotherm correspond to data curves 202 that characterize a change in the percentage of defects when the semiconductor material is annealed at 100° C., 200° C., 300° C., 400° C., 500° C., 600° C., 700° C., 1000° C., and 1200° C. The data curves 202 illustrate that, as the annealing temperatures increase from 100° C. to 1200° C., the percentage of defects decreases with annealing time. Increasing both annealing temperature and annealing time allows the uranium oxide to regenerate a state substantially free of radiation damage. For a diode that includes uranium oxide as the semiconductor material, the state substantially undamaged by radiation may correspond to a loss in conversion efficiency of no greater than 15% relative to a semiconductor material unexposed to radiation.

It will be appreciated that uranium oxide exhibits a higher dielectric constant than conventional semiconductor materials (e.g., Si, GaAs, and GaN). As such, the higher dielectric constant may allow, among other benefits, smaller diode structures. In some embodiments, the diode is a plurality of diodes electrically-coupled in series, in parallel, or any combination thereof. In these embodiments, a presence of uranium oxide within the semiconductor material may allow the plurality of diodes to display a higher packaging density that that associated with conventional semiconductor materials.

In some embodiments, an insulating layer is disposed onto the diode. The insulating layer includes an oxide material and may protect the structure of the diode while operating at temperatures greater than 300° C. In some instances, the oxide material has a melting temperature greater than 500° C. In other instances, the oxide material has a melting temperature greater than 1000° C. In still other instances, the oxide material has a melting temperature greater than 1500° C. In yet other instances, the oxide material has a melting temperature greater than 2000° C. The oxide material may also have a dielectric constant greater than 20. Non-limiting examples of the oxide material include a hafnium oxide material and a strontium titanium oxide material.

In some embodiments, the diode has a trench pattern disposed along a surface thereof. The trench pattern may have an aspect ratio of up to 100:1, a width ranging from 10 nm to 20 μm, and a depth ranging from 12 μm to 1 mm. In further embodiments, the radiation source may include a solid in conformal contact with the trench pattern. The radiation source may also include a fluid in conformal contact with the trench pattern.

In some embodiments, the device includes a connector coupled to the diode and formed of a refractory metal. The refractory metal may be selected from the group consisting of Mo, Ta, W, Re, Os, Ir, and Pt. In some embodiments, the device includes a connector coupled to the diode and formed of an electrically-conductive ceramic. The electrically-conductive ceramic may be selected from the group consisting of ZnO:Ga, Ga₂O₃:Zn, In₂O₃:Sn, and GaN. In some embodiments, the device can include a plurality of connectors.

In some embodiments, the diode includes a p-n structure or a p-i-n structure. In certain instances of these embodiments, a p-type diode portion of the diode comprises over-stoichiometric uranium oxide, UO₂₊ₓ. In certain instances of these embodiments, an n-type diode portion of the diode comprises under-stoichiometric uranium oxide, UO₂₋ₓ. In certain instances of these embodiments, the p-type diode portion of the diode comprises over-stoichiometric uranium oxide, UO₂₊ₓ and the n-type diode portion of the diode comprises under-stoichiometric uranium oxide, UO₂₋ₓ.

In some embodiments, the semiconductor material is doped with at least one element selected from the group consisting of the lanthanide elements and the actinide elements. In these embodiments, the at least one element can substitute for uranium in the semiconductor material.

It will be appreciated that a band gap of the semiconductor material may be engineered by alloying with other oxide materials. Such engineering may involve altering a magnitude of the band gap, establishing an indirect or direct band gap, or both.

In some embodiments, the semiconductor material is alloyed with a calcium oxide material, a copper oxide material, a strontium oxide material, a yttrium oxide material, a bismuth oxide material, or any combination thereof. In these embodiments, the semiconductor material may have a band gap ranging from 0.5 to 3.0 eV. In other embodiments, the semiconductor material is alloyed with a zinc oxide material, a gallium oxide material, a lanthanum oxide material, a lutetium oxide material, a thorium oxide material, or any combination thereof. In such embodiments, the semiconductor material may have a band gap ranging from 3.0 to 6.0 eV. In still other embodiments the semiconductor material is alloyed with a beryllium oxide material, an aluminum oxide material, a silicon oxide material, a thorium oxide material, or any combination thereof. In these embodiments, the semiconductor material may have a band gap ranging from 6.0 to 12.0 eV.

In some embodiments, the semiconductor material is alloyed with beryllium oxide material to improve thermal conductivity within the diode. Such improvement may increase a magnitude of the thermal conductivity by a factor of ten. However, other increases in magnitude are possible.

In some embodiments, the radiation source has a specific activity less than 200 GBq/g. In these embodiments, the radiation source may include 232-Th, 238-U, 241-Am or any combination thereof. The radiation source may allow the device to generate electric power less than 0.1 kW per gram of radiation source (i.e., “low” power). Such “low” power generation may enable the device to have an operational lifetime that exceeds 10 years. In certain instances, the operational life time may exceed 20 years.

In other embodiments, the radiation source has a specific activity greater than 500 Gbq/g. In such embodiments, the radiation source may include 238-Pu, 277-Ac, 244-Cm, 210-Po, or any combination thereof. The radiation source may allow the device to generate electric power greater than 0.1 kW per gram of radiation source (i.e., “high” power). When configured for “high power”, the operational lifetime of the device may be up to 5 years. In certain instances, the operational life time may be up to 10 years.

According to an illustrative embodiment, a method for converting energy into electrical power includes the step of absorbing radiation with a diode. The radiation includes alpha particles emitted from an isotope. The diode is formed of a semiconductor material capable of mitigating radiation damage by operating at temperatures greater than 300° C. The method also includes the step of generating electrical power from the diode in response to the absorbed radiation. In some embodiments, the semiconductor material includes uranium oxide, UO₂, where 0≦x≦0.5. In some embodiments, the step of absorbing radiation within the diode includes receiving radiation from a trench pattern disposed along a surface of the diode.

In some embodiments, the method further includes the step of altering an operating temperature of the diode to an annealing temperature. In some instances of these embodiments, the annealing temperature is greater than 300° C. In other instances of these embodiments, the annealing temperature is greater than 500° C. In still other instances of these embodiments, the annealing temperature is greater than 1000° C. In yet other instances of these embodiments, the annealing temperature is ranges from 300° C. and 2000° C.

The step of altering the operating temperature may include the step of heating the diode by absorbing the radiation. The step of altering the operating temperature may also include the step of regulating the operating temperature with a heat sink thermally-coupled to the diode. The step of altering the operating temperature may occur while generating electrical energy from the diode.

In addition to the illustrative embodiments described above, the devices described in relation to FIGS. 1A, 1B, and 2 may utilize a sandwiched configuration that involves a pair of diodes (e.g., a “flip-chip” configuration). The sandwiched configuration may increase collection of radiation from the radiation source. Many examples of sandwiched configurations are within the scope of the disclosure, some of which are detailed below.

### Example 1

A device having a sandwiched configuration for improving conversion of radiation into electrical energy, the device comprising:
A pair of diodes oriented such that a first surface of a first diode faces a second surface of a second diode, the first surface and the second surface both associated with p-type diode portions or n-type diode portions, the first diode and the second diode formed of a semiconductor material capable of mitigating radiation damage by operating at temperatures greater than 300° C.; and
a radiation source comprising an isotope emitting alpha particles, the radiation source disposed between the first surface and the second surface.

### Example 2

The device of Example 1, wherein the semiconductor material comprises uranium oxide, UO₂, where 0≦x≦0.5.

### Example 3

The device of Example 1, wherein the pair of diodes is a plurality of diode pairs electrically-coupled in series, in parallel, or any combination thereof.

### Example 4

The device of Example 1, wherein the first diode comprises a p-n structure or a p-i-n structure and wherein the second diode comprises a p-n structure or a p-i-n structure.

### Example 5

The device of Example 1,
wherein a trench pattern is etched into the first surface and the second surface; and
wherein the radiation source comprises a solid in conformal contact with the trench pattern on the first surface and the second surface.

### Example 6

The device of Example 1,
wherein a channel pattern is etched into the first surface and the second surface; and
wherein the radiation source comprises a fluid in conformal contact with the channel pattern on the first surface and the second surface.

### Example 7

The device of Example 6,
wherein the channel pattern of the first surface contacts the channel pattern of the second surface so as to define a plurality of enclosed conduits through the pair of diodes; and
wherein the radiation source comprises the fluid disposed within the plurality of enclosed conduits.

The devices described in relation to FIGS. 1A, 1B, and 2 may also utilize a stacked configuration that involves a stacked sequence of diodes. The stacked configuration may improve collection of radiation from the radiation source. Many examples of stacked configurations are within the scope of the disclosure, some of which are detailed below.

### Example 8

A device having a stacked configuration for improving conversion of radiation into electrical energy, the device comprising:
a stacked sequence of diodes that alternate between a first junction defined by adjacent p-type diode portions and a second junction defined by adjacent n-type diode portions, each diode formed of a semiconductor material capable of mitigating radiation damage by operating at temperatures greater than 300° C.; and
a radiation source comprising an isotope emitting alpha particles, the radiation source disposed within the first junction, the second junction, or both.

### Example 9

The device of Example 8, wherein the semiconductor material comprises uranium oxide, UO_{2±x}, where 0≦x≦0.5.

### Example 10

The device of Example 8, the stacked sequence of diodes comprises a plurality of stacked sequences electrically-coupled in series, in parallel, or any combination thereof

### Example 11

The device of Example 8, wherein each diode comprises a p-n structure or a p-i-n structure.

### Example 12

The device of Example 8, wherein the radiation source comprises a solid in contact with adjacent p-type diode portions of the first junction, adjacent n-type diode portions of the second junction, or both.

### Example 13

The device of Example 12,
wherein a trench pattern is disposed along adjacent surfaces of, respectively, the p-type diode portions of the first junction, the n-type diode portions the second junction, or both; and
wherein the solid is in conformal contact with the trench pattern.

### Example 14

The device of Example 8, wherein the radiation source comprises a fluid in contact with adjacent p-type diode portions of the first junction, adjacent n-type diode portions of the second junction, or both.

### Example 15

The device of Example 14,
wherein a channel pattern is etched into adjacent surfaces of, respectively, the p-type diode portions of the first junction, the n-type diode portions the second junction, or both; and
wherein the fluid is in conformal contact with the channel pattern.

### Example 16

The device of Example 14,
wherein the channel pattern is etched into adjacent surfaces of, respectively, the p-type diode portions of the first junction, the n-type diode portions the second junction, or both;
wherein the channel patterns of adjacent surfaces contact within each junction so as to define a plurality of enclosed conduits; and
wherein the fluid is disposed within the plurality of enclosed conduits.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A device for converting energy from radiation into electrical power, the device comprising:
a diode formed of a semiconductor material capable of mitigating radiation damage by operating at temperatures greater than 300° C.; and
a radiation source comprising an isotope emitting alpha particles.

2. The device of claim 1, wherein the semiconductor material comprises an oxide semiconductor having a majority component that comprises an actinide element.

3. The device of claim 1, further comprising a connector coupled to the diode and formed of an electrically-conductive material stable to at least 300° C.

4. The device of claim 1, wherein the diode comprises a p-n structure or a p-i-n structure.

5. The device of claim 1, wherein the diode is a plurality of diodes electrically-coupled in series, in parallel, or any combination thereof.

6. The device of claim 1, wherein the radiation source has a specific activity less than 200 GBq/g.

7. The device of claim 6, wherein the isotope of the radiation source comprises 232-Th, 238-U, 241-Am, or any combination thereof.

8. The device of claim 1, wherein the radiation source has a specific activity greater than 500 GBq/g.

9. The device of claim 8, wherein the isotope of the radiation source comprises 238-Pu, 277-Ac, 244-Cm, 210-Po, or any combination thereof.

10. The device of claim 1, wherein the semiconductor material has a band gap ranging from 0.5 to 3.0 eV.

11. The device of claim 1, wherein the semiconductor material has a band gap ranging from 3.0 to 6.0 eV.

12. The device of claim 1, wherein the semiconductor material has a band gap ranging from 6.0 to 12.0 eV.

13. The device of claim 1, wherein the semiconductor material has a thermal conductivity between greater than 1 W/(m·K), as measured at 20° C.

14. The device of claim 1, wherein the diode has a trench pattern disposed along a surface thereof.

15. The device of claim 14, wherein the trench pattern has an aspect ratio of up to 100:1, a width ranging from 10 nm to 20 μm, and a depth ranging from 12 μm to 1 mm.

16. A device having uranium oxide for converting energy from radiation into electrical power, the device comprising:
a diode formed of a semiconductor material comprising uranium oxide, UO_{2±x}, where 0≦x≦0.5; and
a radiation source comprising an isotope emitting alpha particles.

17. The device of claim 16, wherein the semiconductor material comprises a single-crystal of uranium oxide.

18. The device of claim 16, further comprising a connector coupled to the diode and formed of a refractory metal.

19. The device of claim 16, further comprising a connector coupled to the diode and formed of an electrically-conductive ceramic.

20. The device of claim 16, wherein the diode comprises a p-n structure or a p-i-n structure.

21. The device of claim 20, wherein a p-type diode portion of the diode comprises over-stoichiometric uranium oxide, UO₂₊ₓ.

22. The device of claim 20, wherein an n-type diode portion of the diode comprises under-stoichiometric uranium oxide, UO₂₋ₓ.

23. The device of claim 16, wherein the semiconductor material is doped with at least one element selected from the group consisting of the lanthanide elements and the actinide elements.

24. The device of claim 16, wherein the radiation source has a specific activity less than 200 GBq/g.

25. The device of claim 16, wherein the radiation source has a specific activity greater than 500 GBq/g.

26. The device of claim 16, wherein the semiconductor material is alloyed with a calcium oxide material, a copper oxide material, a strontium oxide material, a yttrium oxide material, a bismuth oxide material, or any combination thereof.

27. The device of claim 16, wherein the semiconductor material is alloyed with a zinc oxide material, a gallium oxide material, a lanthanum oxide material, a lutetium oxide material, a thorium oxide material, or any combination thereof.

28. The device of claim 16, wherein the semiconductor material is alloyed with a beryllium oxide material, an aluminum oxide material, a silicon oxide material, a thorium oxide material, or any combination thereof.

29. The device of claim 16, wherein the diode has a trench pattern disposed along a surface thereof.

30. The device of claim 29, wherein the radiation source is in conformal contact with the trench pattern.

31. The device of claim 29, wherein the trench pattern has an aspect ratio of up to 100:1, a width ranging from 10 nm to 20 μm, and a depth ranging from 12 μm to 1 mm.

32. A method for converting energy from radiation into electrical power, the method comprising:
absorbing radiation within a diode, the radiation comprising alpha particles emitted from an isotope;
generating electrical power from the diode in response to the absorbed radiation; and
wherein the diode is formed of a semiconductor material capable of mitigating radiation damage by operating at temperatures greater than 300° C.

33. The method of claim 32, further comprising altering an operating temperature of the diode to an annealing temperature.

34. The method of claim 33, wherein altering the operating temperature occurs while generating electrical energy from the diode.

35. The method of claim 33, wherein the annealing temperature is greater than 300° C.

36. The method of claim 33, wherein the annealing temperature is greater than 500° C.

37. The method of claim 33, wherein the annealing temperature is greater than 1000° C.

38. The method of claim 33, wherein altering the operating temperature comprises heating the diode by absorbing the radiation.

39. The method of claim 33, wherein altering the operating temperature comprises regulating the operating temperature with a heat sink thermally-coupled to the diode.
